(19) United States
(12) Patent Application Publication
(10) Pub. No.: US 2016/0155491 A1
(43) Pub. Date: Jun. 2, 2016

(54) MEMORY PERSISTENCE MANAGEMENT CONTROL

(71) Applicant: Advanced Micro Devices, Inc., Sunnyvale, CA (US)

(72) Inventors: David A. Roberts, Santa Cruz, CA (US); Michael Ignatowski, Austin, TX (US)

(21) Appl. No.: 14/555,639

(22) Filed: Nov. 27, 2014

(51) Int. Cl. G11C 11/406

(52) U.S. Cl. CPC G11C 11/40607; G11C 11/40626

(57) ABSTRACT

A memory retention controller may include a data structure configured to store a memory refresh interval corresponding to a memory region in a memory subsystem and control logic coupled with the data structure. The control logic is configured to perform a first refresh of the memory region prior to a power off transition of a host processor coupled with the memory subsystem, and to perform a second refresh of the memory region after the power off transition of the host processor, based on the memory refresh interval corresponding to the memory region, and in response to an elapsed time since the first refresh of the memory region.

### GOVERNMENT RIGHTS

This invention was made with Government support under Prime Contract Number DE-AC52-07NA27344, Subcontract Number B600716 awarded by DOE. The Government has certain rights in this invention.

### TECHNICAL FIELD

This disclosure relates to the field of memory and, in particular, to management of retention operations for memory.

### BACKGROUND

Memory refresh is the process of reading data from memory and immediately rewriting the read information to the same location in the memory from which it was read. In many modern computing systems, memory refresh is performed periodically in order to preserve the information. In particular, memory technologies such as dynamic random access memory (DRAM) are periodically refreshed so that the data stored in the DRAM is not degraded or lost over time.

In a DRAM chip, each memory cell stores a bit of data as the presence or absence of electric charge on a capacitor; thus, over time, the stored charge can leak, resulting in the loss of the stored data bit. With each memory refresh, the electric charge is restored to its original level so that the data bit can be retained over a longer period of time.

Computing systems may vary in the types of memories they use; thus, different platforms can employ multiple types and configurations of memory that have different retention times. For example, DRAM memory cells may be refreshed on the order of once every 32 milliseconds, whereas NAND Flash memory may be refreshed on the order of once a year. Other memories such as STT-MRAM can trade off latency with retention time, and may be refreshed once every hour, for example.

### BRIEF DESCRIPTION OF THE DRAWINGS

The present disclosure is illustrated by way of example, and not by way of limitation, in the figures of the accompanying drawings.

FIG. 1 illustrates an embodiment of a computing system.

FIG. 2 illustrates a memory subsystem, according to an embodiment.

FIG. 3 illustrates a memory retention controller and memory regions, according to an embodiment.

FIG. 4 is a flow diagram illustrating a memory maintenance process, according to an embodiment.

FIG. 5 illustrates a processor-in-memory system including a memory retention controller, according to an embodiment.

### DETAILED DESCRIPTION

The following description sets forth numerous specific details such as examples of specific systems, components, methods, and so forth, in order to provide a good understanding of the embodiments. It will be apparent to one skilled in the art, however, that at least some embodiments may be practiced without these specific details. In other instances, well-known components or methods are not described in detail or are presented in a simple block diagram format in order to avoid unnecessarily obscuring the embodiments. Thus, the specific details set forth are merely exemplary. Particular implementations may vary from these exemplary details and still be contemplated to be within the spirit and scope of the embodiments.

One embodiment of a computing system includes a memory retention controller that is capable of managing memory retention operations, such as periodic memory refresh, for one or more different types of memories having different data retention characteristics. For example, such a computing system may store data in a first type of memory, such as DRAM, that has a relatively short refresh interval, and may store other data in a second type of memory, such as NAND memory, that has a relatively long refresh interval. Accordingly, the memory retention controller keeps track of the refresh intervals for memory regions including the same or different types of memory, and triggers the memory refresh process for each of these regions according to their respective refresh intervals. The memory retention controller stores a retention period expiration time for each memory region as a timestamp, where the retention period expiration time indicates a time at or before which the next memory refresh is scheduled to occur so that data will not be lost. The stored refresh intervals and retention period expiration times can be adjusted at runtime, or while the memory regions are in use, to accommodate memory cell mode changes or changing environmental factors.

In one embodiment, the memory retention controller can perform other memory maintenance operations, such as data migration or memory scrubbing, prior to the retention period expiration time. The memory retention controller may continue operating even when the host system in which it is implemented is in a low power consumption state (e.g., an Advanced Configuration and Power Interface (ACPI) G1 power state), and is also capable of waking a host processor from a low power consumption state and causing the host processor to perform one or more of the memory maintenance operations.

Thus, embodiments of the memory retention controller can be used in computing systems utilizing multiple memory technologies with varying retention characteristics, and/or in computing systems having memory with a longer refresh interval than the typical power cycle time of the computing system. In such a computing system, the host processor may be powered on and off one or more times within the duration of a single refresh interval.

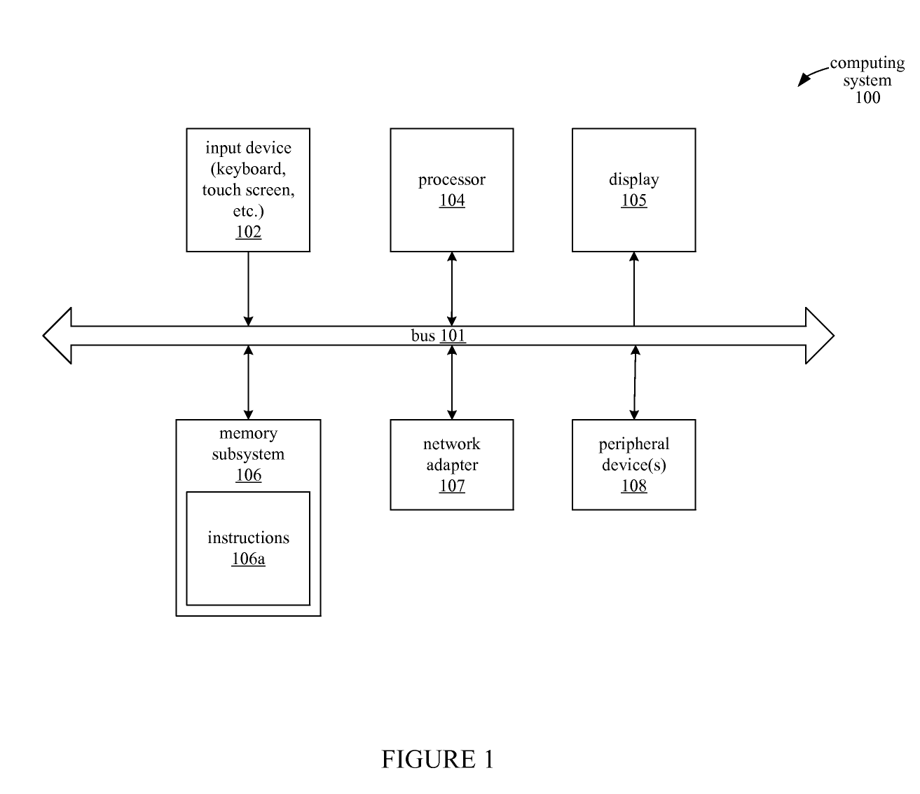

FIG. 1 illustrates an embodiment of a computing system 100 which may implement a memory retention controller as described above. In general, the computing system 100 may be embodied as any of a number of different types of devices, including but not limited to a laptop or desktop computer, mobile phone, server, etc. The computing system 100 includes a number of components 102-108 that can communicate with each other through a bus 101. In computing system 100, each of the components 102-108 is capable of communicating with any of the other components 102-108 either directly through the bus 101, or via one or more of the other components 102-108. The components 101-108 in computing system 100 are contained within a single physical casing, such as a laptop or desktop chassis, or a mobile phone casing. In alternative embodiments, some of the components of computing system 100 may be embodied as peripheral devices such that the entire computing system 100 does not reside within a single physical casing.

The computing system 100 also includes user interface devices for receiving information from or providing information to a user. Specifically, the computing system 100 includes an input device 102, such as a keyboard, mouse, touch-screen, or other device for receiving information from the user. The computing system 100 displays information to the user via a display 105, such as a monitor, light-emitting diode (LED) display, liquid crystal display, or other output device.

Computing system 100 additionally includes a network adapter 107 for transmitting and receiving data over a wired or wireless network. Computing system 100 also includes one or more peripheral devices 108. The peripheral devices 108 may include mass storage devices, location detection devices, sensors, input devices, or other types of devices that can be used by the computing system 100.

Computing system 100 includes a processor 104 that is configured to receive and execute instructions 106a that are stored in the memory subsystem 106. Memory subsystem 106 includes memory devices used by the computing system 100, such as random-access memory (RAM) modules, read-only memory (ROM) modules, hard disks, and other non-transitory computer-readable media. In one embodiment, the memory subsystem 106 may include logic to implement one or more memory retention controllers each corresponding to a memory region in the memory subsystem 106.

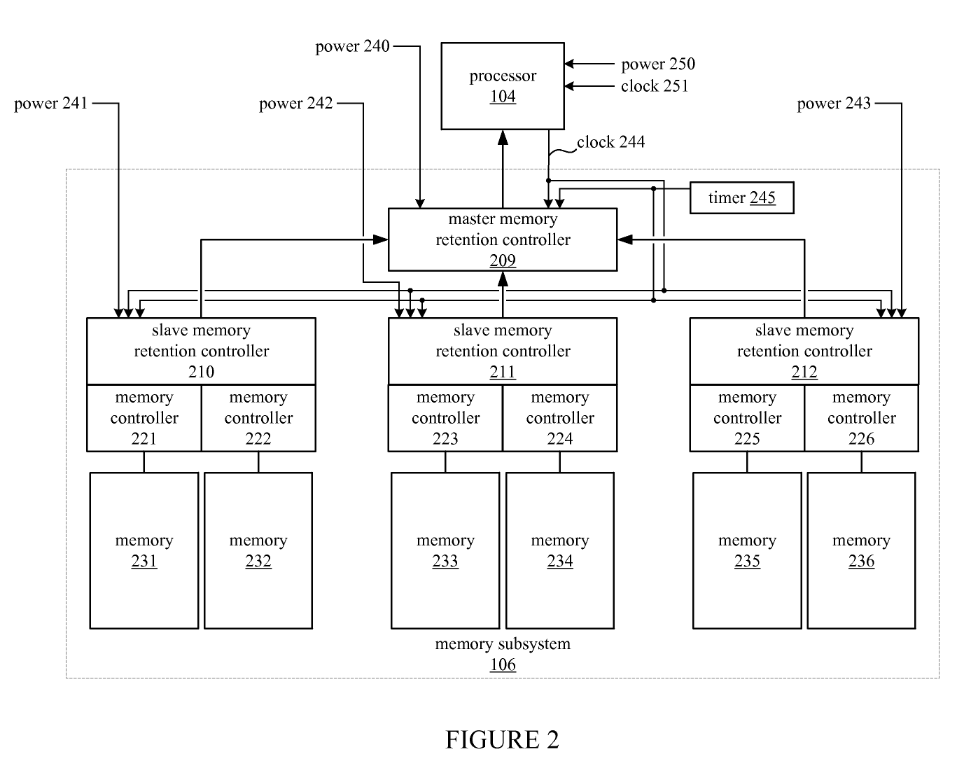

FIG. 2 illustrates an embodiment of a memory subsystem 106 coupled with a processor 104. As illustrated in FIG. 2, the memory subsystem 106 includes multiple memory retention controllers 209, 210, 211, and 212. Alternative embodiments may include fewer or more memory retention controllers. Each of the slave memory retention controllers 210-212 is coupled to the master memory retention controller 209, and to two memory controllers, which are each coupled to a memory region. As illustrated in FIG. 2, the memory controller 210 is coupled with memory controllers 221 and 222, which control the memory in regions 231 and 232, respectively. For example, the memory controller 221 controls memory region 231 and can therefore issue read, write, erase, refresh, and various other commands to the memory cells in region 231.

Memory retention controller 211 is similarly coupled with memory controllers 223 and 224, which control memory regions 233 and 234, respectively. Memory retention controller 212 is similarly coupled with memory controllers 225 and 226, which control memory regions 235 and 236, respectively. In alternative embodiments, a single memory controller may control multiple memory regions.

In one embodiment, the memory retention controllers 209-212 have logic that operates based on a clock or counter 244. Accordingly, an integrated circuit chip in which one of the memory retention controllers 209-212 is implemented includes a low-power and low-frequency external clock signal input so that such a clock signal may be provided to the memory retention controller. In one embodiment, a memory package having a logic for performing memory refreshes may already be provided with an external clock signal input; the same clock signal input may be used to supply the low-power and low-frequency clock signal to the memory retention controller while the host system is operating in a low power consumption state (e.g., ACPI G1).

The memory retention controllers 209-212 operate on a different clock domain than the host processor 104. For example, while the memory retention controllers operate using clock signal 244, the host processor 104 operates using a different clock 251. In one embodiment, as illustrated in FIG. 2, the clock 244 is provided by the host processor; alternatively, the clock 244 may be provided from a different source or may be generated within the same package as the memory retention controller. The memory retention controllers 209-212 can optionally synchronize with an external clock (e.g., via radio or internet signal) to accurately determine the current time.

In one embodiment, the clock signal 244 supplied to the memory retention controllers 209-212 has a lower frequency than the clock signal 251 supplied to the host processor 104. With a relatively lower frequency clock, the memory retention controllers 209-212 may be implemented using a low powered circuit technology that is different from what is used in the host processor, such as low powered near-threshold logic.

The computing system 100 includes a first power domain to supply power to the host processor 104 and at least one other power domain for supplying power to the memory retention controllers 209-212. For example, the processor 104 is supplied from a power source 250, while the memory retention controllers 209, 210, 211, and 212 are supplied from power sources 240, 241, 242, and 243, respectively. The power sources 250 and 240-243 operate independently from each other, so that the processor 104 and each of the memory retention controllers 209-212 can be independently powered down or transitioned to low power consumption states.

In one embodiment, each of the power supplies 240-243 for the memory retention controllers 209-212 is an auxiliary power supply capable of supplying power to its corresponding memory retention controller even when the host processor 104 and/or the remainder of the computing system 100 is in a powered off state or in a low power consumption state. For example, the memory retention controllers 209-213 may operate using backup or battery power while the host processor 104 and the remainder of the computing system 100 is in one of the ACPI G1 power states.

In one embodiment, while the host processor 104 is powered off or operating in a low power consumption state, one or more of the memory retention controllers 209-213 are also maintained in a low power consumption state. The memory retention controllers 209-213 can be transitioned to a higher power consumption state in order to check for impending refresh events or other scheduled memory maintenance events using a timer circuit 245 that outputs a wake signal prior to the time at which the next refresh event or memory maintenance operation is due.

In one embodiment, the memory retention controllers 209-212 in the memory subsystem 106 are connected in a hierarchical arrangement, with multiple slave memory retention controllers 210-212 each coupled with a master memory retention controller 209 via a command channel. Alternative embodiments may include additional levels of hierarchy, with each slave memory retention controller serving as a master memory retention controller with respect to one or more additional levels of slave memory retention controllers. Such an extended hierarchy may be used to scale the system to manage retention for more memory or for a greater number of different memory regions. Alternatively, some embodiments may forgo the hierarchical arrangement and implement only a single level of one or more memory retention controllers between the processor and the managed memory regions 231-236.

In memory subsystem 106, the slave memory retention controllers 210-212 are each responsible for tracking refresh intervals and performing memory retention operations at the appropriate times for their assigned memory regions, which can be represented as memory address ranges. Specifically, memory retention controller 210 performs memory retention operations for memory regions 231 and 232, memory retention controller 211 performs memory retention operations for memory regions 233 and 234, and memory retention controller 212 performs memory retention operations for memory regions 235 and 236. Accordingly, each of the memory retention controllers 210-212 stores one or more memory refresh intervals corresponding to their assigned memory regions. For example, memory retention controller 210 stores memory refresh intervals for memory regions 231 and 232.

The memory retention controllers 210-212 are each coupled with memory controllers for controlling their assigned memory regions 231-236; for example, memory retention controller 210 is coupled to memory regions 231 and 232 through memory controllers 221 and 222, respectively. The memory retention controller 210 can thus issue commands or otherwise cause the memory controllers 221 and 222 to perform memory retention operations on the memory regions 231 and 232 at the appropriate intervals, according to the retention periods for the regions 231 and 232. In alternative embodiments, the memory retention controller may be integrated with the memory controller logic.

With the memory retention controllers 209-212 arranged in a hierarchical structure, the slave memory retention controllers 210-212 each are able to cause the master memory retention controller 209 to transition from a low power consumption state to a higher power consumption state in order to initiate one or more memory maintenance operations on the memory regions 231-236 assigned to the slave memory retention controllers 210-212. For example, slave memory retention controller 211 keeps track of the retention periods for the memory regions 233 and 234. Prior to the expiration of the retention period (as determined by the refresh interval or another time-out), the slave memory retention controller 211 causes the master memory retention controller 209 to transition from a low power consumption state to a higher power consumption state. After transitioning to the higher power consumption state, the master memory retention controller 209 may execute a command initiated by one of the slave memory retention controllers 210-212.

In one embodiment, the slave memory retention controllers 210-212 are configurable to handle refresh events without waking a master memory retention controller. Each of the slave memory retention controllers 210-212 stores a bit for each of its associated memory ranges indicating whether refresh events should be propagated to the master memory retention controller 209. For example, a set bit may indicate that refresh events should be propagated to and/or serviced by the master memory retention controller 209, while an unset bit indicates that refresh events are to be serviced by the slave memory retention controller without propagating the event to the master memory retention controller 209.

In one embodiment, one of the slave memory retention controllers 210-212 may request that a command be executed by the host processor 104. In this case, the master memory retention controller 209 may additionally cause the host processor 104 to transition from a low power consumption state to a higher power consumption state. Once the master memory retention controller 209 and host processor 104 are in higher power consumption states, interrupts and commands can be propagated from any of the slave memory retention controllers 210-212 through the master memory retention controller 209 to the host processor 104 to be serviced or executed.

The commands that can be requested by the memory retention controllers and executed by the host processor 104 may include memory maintenance operations, such as data migration or data scrubbing, for example. A slave memory retention controller may thus, in response to determining that a memory maintenance operation is scheduled to take place for one of its assigned memory regions, cause the host processor 104 to transition from a low power consumption state to perform the memory maintenance operation on the memory region.

Interrupts and commands can also be propagated from the host processor 104 to any of the slave memory retention controllers 210-212. In order to send a command to a specific memory retention controller, the processor 104 specifies a value identifying the destination memory retention controller that is transmitted along with the command. The master memory retention controller 209 then transmits the command to the appropriate destination slave memory retention controller.

In an alternative embodiment, the master memory retention controller 209 keeps track of the refresh intervals for each of the memory regions 231-236 instead of the slave memory retention controllers 210-212. The master memory controller 209 signals to the corresponding slave memory controller when a memory refresh is due for a particular memory region. The slave memory controller performs the refresh of the memory region in response to the signal from the master memory retention controller 209.

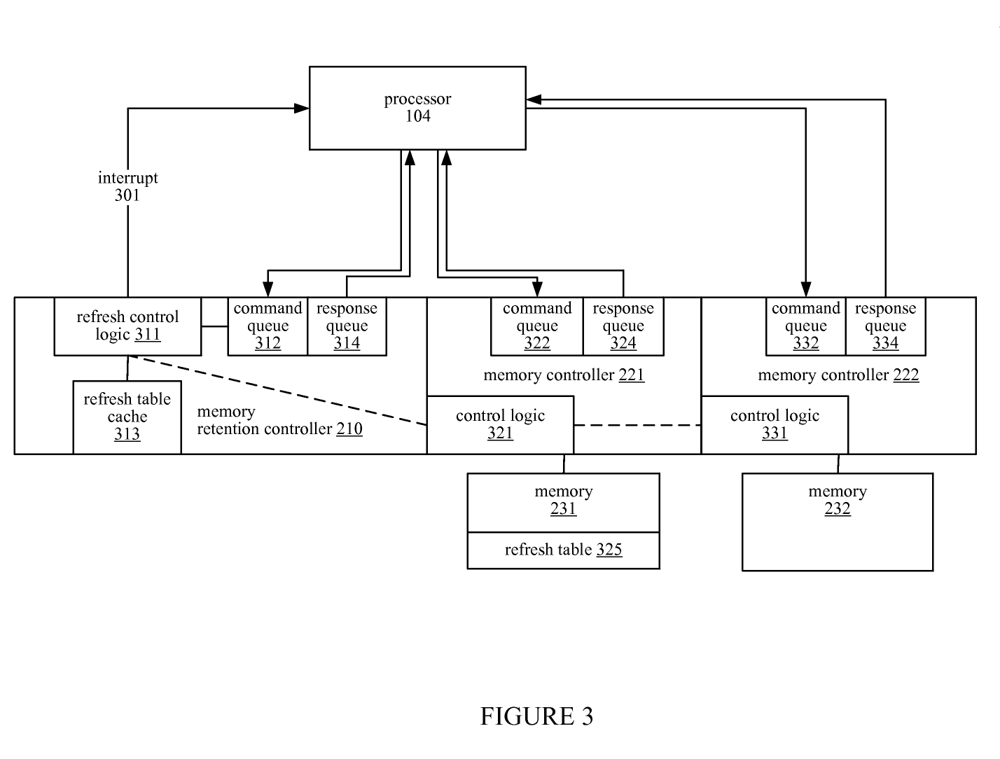

FIG. 3 illustrates a more detailed view of a single memory retention controller 210 and its corresponding memory regions 231 and 232, according to an embodiment. The memory retention controller 210 is coupled to the memory regions 231 and 232 via the memory controllers 221 and 222, respectively. The refresh control logic 311 of the memory retention controller 210 is coupled to communicate with the memory controllers 221 and 222 for the respective memory regions 231 and 232. The memory controllers are configured to perform operations on the memory regions, including read, write, activate, precharge, erase, and refresh operations. In one embodiment, the memory controllers 221 and 222 may also be capable of entering a self-refresh mode, in which the memory controller periodically performs the refresh operation on its associated memory region.

In one embodiment, each of the memory retention controller 210 and the memory controllers 221 and 222 includes a command queue 312, 322, and 332, respectively. Each of the command queues 312, 322 and 332 is used to store commands from the processor 104 that are directed at one of the controllers 210, 221, and 222. The controllers 210, 221, and 222 may also store outgoing messages or commands in their respective response queues 314, 324, and 334 where the messages or commands can be retrieved by processor 104. In an alternative embodiment, the controllers 210, 221, and 222 share a single command queue and a single response queue rather than each having individual command and response queues.

Examples of commands that can be stored in the command queues 322 and 332 of the memory controllers 221 and 222 include commands for initiating the read, write, activate, precharge, erase, and refresh operations or for causing the memory controller to enter the self-refresh mode. Commands received in the command queues are executed by the control logic 321 and 331 of the memory controllers 221 and 222, respectively. The memory controllers 221 and 222 can also place commands in their respective response queues 324 and 334 to be retrieved and serviced by the processor 104.

Commands that can be stored in the command queue 312 of the memory retention controller 210 may include commands for performing various memory maintenance operations such as, for example, commands for forcing refresh of a range of memory addresses, for querying for the next refresh time for a range of memory addresses, for setting a refresh interval for a range of memory addresses, for performing memory scrubbing for a range of addresses, and for writing back or flushing the refresh table cache 313. Commands received in the command queue may be executed by the refresh control logic 311, or may be forwarded to the control logic 321 or 331 for execution. The refresh control logic 311 can also place commands in the response queue 314 to be retrieved and serviced by the processor 104.

The refresh table 325 is a data structure for storing one or more memory refresh intervals each corresponding to one of the memory regions in the memory subsystem 106, and may be stored in a reliable region of a persistent memory. As illustrated in FIG. 3, the refresh table 325 is stored in the memory region 231. In one embodiment, a refresh table for each memory region can be stored in the memory region itself. In alternative embodiments, the refresh table may be stored in a volatile or non-volatile memory separate from its associated memory region.

The refresh table 325 can be subject to wear leveling and error-correction code (ECC) mechanisms. In one embodiment, the ECC scheme applied to the refresh table 325 is stronger than the rest of memory. Alternatively, if each memory region stores its own refresh table, then wear leveling and ECC can be applied to the refresh table along with the rest of the data in the memory region.

The memory regions in the memory subsystem 106 are identified as address ranges; thus, the refresh table 325 includes records that indicate a refresh interval for each address range, along with a timestamp indicating a time at which the next refresh is to be performed for the memory region. In one embodiment, bloom filters may be used to record the addresses corresponding to each refresh interval.

The refresh control logic 311 performs a memory refresh at the time indicated by the next refresh time timestamp, as stored in the refresh table 325. In one embodiment, the refresh table can be sorted in order of the next refresh time to minimize the search time for finding memory regions to refresh; alternatively, the refresh control logic 311 can search the table 325 or table cache 313 to find memory regions due to be refreshed if the entries are not sorted in order of the next refresh time.

The information stored in the refresh table 325 is additionally cached in faster and lower latency memory in the refresh table cache 313 for quick access by the refresh control logic 311, increasing the speed at which pending memory refresh operations can be serviced. All or part of the data in the refresh table 325 can be cached in the refresh table cache 313.

A memory refresh interval stored in the refresh table 325 for a memory region may be adjusted in response to environmental changes or other factors that impact retention time of the memory cells in that region. For example, the computing system 100 may include one or more temperature sensors for detecting temperature of the memory cells in the memory region, or ambient temperature surrounding the memory region. As the temperature increases, the retention time of the memory decreases; accordingly, the refresh control logic 311 decreases the refresh interval for the memory region in response to detecting an increase in temperature so that the memory cells are refreshed more frequently. Thus, the refresh control logic 311 may perform a series of memory refreshes for memory cells in the memory region at a first frequency prior to a change in the refresh interval; then, in response to a change in the memory refresh interval, the refresh control logic 311 may continue performing the memory refreshes at a different frequency indicated by the new memory refresh interval.

In one embodiment, updates to the refresh table 325 may be performed via the refresh table cache 313 as write-through operations. In particular, reductions in a memory refresh interval for a region are performed in a write-through manner so that both the cache 313 and the backing store of the cache 313 (i.e., refresh table 325) are updated concurrently or substantially close in time that no intervening operations are likely to take place. Writing-through the cache 313 for reductions in the memory refresh interval decreases the likelihood of a new retention time being exceeded due to use of an old refresh interval that is longer than the new refresh interval. In an alternative embodiment, updates to the memory retention interval can be stored in the cache 313 in a log format, with a version number for each update.

In addition to performing memory refreshes, the refresh control logic 311 can also initiate other memory maintenance operations. The refresh control logic 311 can signal the processor 104 via interrupt line 301 in order to initiate a memory maintenance operation to be performed by the processor 104. If the processor 104 and/or the computing system 100 are operating in a low power consumption state (e.g., ACPI G1), the asserted interrupt line 301 may cause the processor 104 to transition to a higher power consumption state in order to service the request to perform the memory maintenance operation. Memory maintenance operations that may be requested by the refresh control logic 311 may include, for example, memory refreshes, memory scrubbing, data migration, or other operations for maintaining data integrity and preventing data loss.

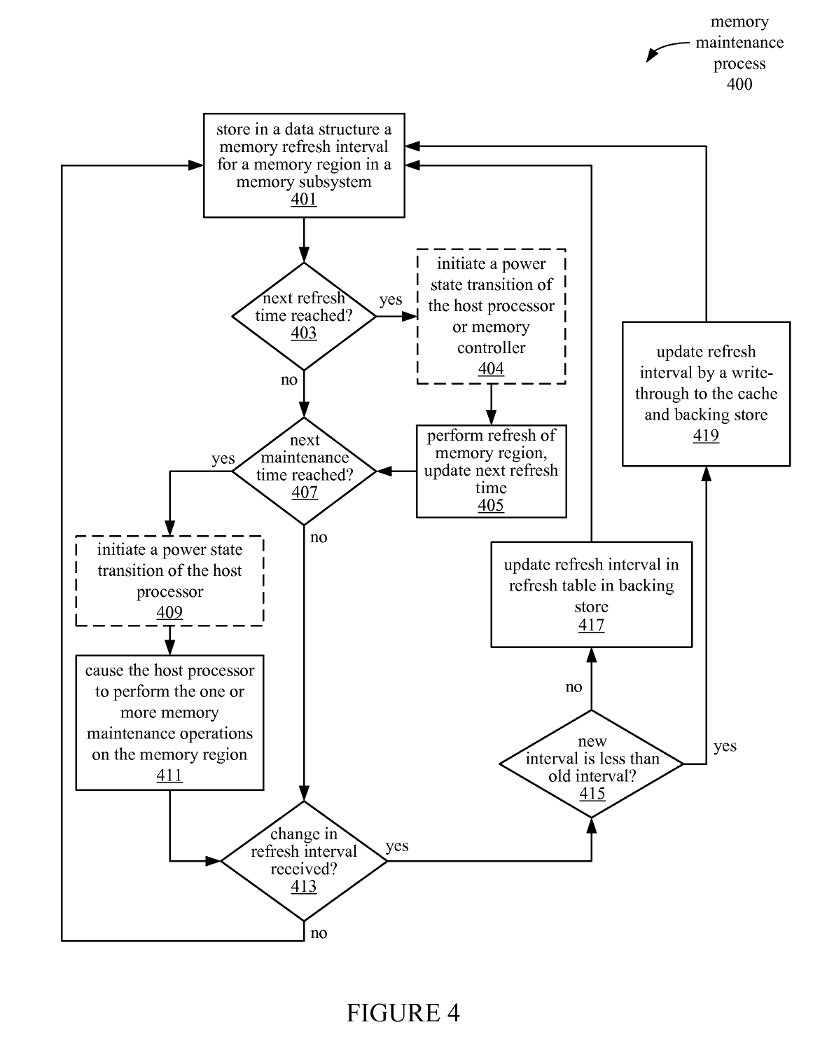

FIG. 4 illustrates a memory maintenance process 400 for performing memory refreshes and other memory maintenance operations on one or more memory regions in a memory subsystem 106, according to one embodiment. The operations in process 400 are performed by components of the memory subsystem 106, including the memory retention controller 210 and refresh table 325. The memory maintenance process 400 begins at block 401.

At block 401, the refresh table 325 stores a memory refresh interval for the memory regions 231 and 232 in the memory subsystem 106. The memory refresh intervals indicate a frequency at which memory refreshes are to be performed for the associated memory region. The refresh table 325 may additionally store memory maintenance intervals for the memory regions, where the memory maintenance intervals indicate the frequency at which one or more memory maintenance operations are to be performed on the associated memory regions.

In one embodiment, storing the memory refresh intervals and memory maintenance intervals includes storing these values in a reliable persistent memory, such as refresh table 325 in memory 231 or alternatively, in a separate memory such as a non-volatile memory module. The refresh table 325 may additionally be cached in the refresh table cache 313 for quick access by the refresh control logic. From block 401, the process 400 continues at block 403.

In addition to the memory refresh intervals and memory maintenance intervals, the refresh table 325 and associated cache 313 also stores next refresh times and next maintenance times for each of the memory regions. Each of these next action times may be recorded as a timestamp indicating the next time at which the refresh or memory maintenance operations is due, and is determined by the refresh control logic 311 based on the memory refresh and memory maintenance intervals for the memory region.

At block 403, the refresh control logic 311 determines whether the next refresh time has been reached for any of the memory regions. In one embodiment, the refresh control logic compares the current time with the timestamp indicating the next refresh time, which is stored in the refresh table 325 or its cache 313. At block 403, if the next refresh time has been reached, the refresh control logic 311 performs a refresh of the memory region associated with the next refresh time. Otherwise, if the next refresh time has not been reached, the process 400 continues at block 407.

In one embodiment, the refresh control logic 311 may perform the refresh by requesting the memory controller to perform the refresh of the memory region or by requesting the host processor to initiate the memory refresh of the memory region. At block 404, if the host processor or memory controller is in a low power consumption state, the refresh control logic 311 can initiate a power state transition of the host processor or the memory controller to a higher power consumption state so that the host processor or memory controller can perform the memory refresh. For example, the refresh control logic 311 can wake the memory controller 221 by signaling control logic 321, or wake the processor 104 via interrupt 301.

At block 405, the refresh control logic 311 performs the memory refresh of the memory region 231 by causing the host processor 104 or the memory controller 221 to perform the memory refresh (i.e., the n^{th} memory refresh in a series of memory refreshes). Alternatively, the refresh control logic 311 may perform the memory refresh on the memory region 231 without waking the host processor 104 or memory controller 221 as provided in block 404. At block 405, the refresh control logic 311 also updates the next refresh time, corresponding to the (n+1)^{th} refresh, according to the memory refresh interval associated with the memory region by adding the memory refresh interval to the time of the n^{th} memory refresh. Accordingly, the next subsequent (i.e., (n+1)^{th}) memory refresh of the memory region is performed at a time determined based on the memory refresh interval and in response to an elapsed time since the n^{th} refresh of the memory region. From block 405, the process 400 continues at block 407.

At block 407, the refresh control logic 311 determines whether a memory maintenance operation is due by determining whether the next maintenance time has been reached for any of the memory regions. In one embodiment, the refresh control logic 311 compares the current time with the timestamp indicating the next memory maintenance time, which is stored in the refresh table 325 or in its cache 313. In one embodiment, a next memory maintenance time for a particular memory region is used to indicate a time before a retention failure of the memory region is likely to occur. At block 407, if the next maintenance time has been reached for any of the memory regions, the process 400 continues at block 409.

At block 409, if the host processor 104 is operating in a low power consumption state, the refresh control logic 311 can initiate a power state transition of the host processor 104 to a higher power consumption state so that the host processor 104 can perform the memory maintenance operation. For example, the refresh control logic 311 can wake the processor 104 via interrupt 301. If the host processor 104 is already operating in the higher power consumption state, the refresh control logic 311 may skip block 409. From block 409, the process 400 continues at block 411.

At block 411, the refresh control logic 311 initiates one or more memory maintenance operations associated with the next memory maintenance time that is being serviced by causing the processor 104 to perform the one or more memory maintenance operations on the appropriate memory region. In one embodiment, the refresh control logic 311 may flag the memory region and assert the interrupt 301 to cause the processor 104 to perform the one or more memory maintenance operations according to software instructions 106a.

The memory maintenance operations that can be performed at block 411 include operations such as memory scrubbing, data migration operations, or other operations for maintaining data integrity and preventing data loss. A memory scrubbing operation prevents the accumulation of errors in the data by using error correction code (ECC) logic circuits to check the memory locations in the memory region. Thus, the refresh control logic 311 may activate ECC logic in a memory controller or other logic unit to check for errors in the memory region when executing a memory scrubbing operation. Any errors in the data that are found by the ECC logic can also trigger additional memory maintenance operations.

The refresh control logic 311 initiates a data migration operation by requesting the host processor 104 to copy or move data from one memory region to another memory region. For example, refresh control logic 311 may request the processor 104 to move data from a memory region having a lower retention-time memory region to a memory region having a higher retention-time. From block 411, the process 400 continues at block 413.

At block 413, the refresh control logic 311 determines whether a change in the refresh interval has been received. The memory refresh interval may be received by the refresh control logic 311 from the processor 104 via a command placed in the command queue 312. For example, a command placed in the command queue 312 by the processor 104 may identify a memory region for which the refresh interval is to be changed, along with a new refresh interval.

At block 413, if a change in the refresh interval for any of the memory regions has not been received, the process 400 continues back to block 401. Thus, the process 400 repeats blocks 401-413 to perform a series of multiple memory refreshes at a first frequency indicated by the memory refresh interval for each memory region until a change in the refresh interval is received.

In one embodiment, because the memory retention controller 210 is supplied from a separate power domain than the host processor 104, the host processor and/or the other components of the computing system 100 may undergo power state transitions in between the operations of process 400 illustrated in FIG. 4. For example, the host processor 104 and host computing system 100 may be in a powered-on state (e.g., ACPI G0) during a first (i.e., n^{th}) refresh in the series of multiple refreshes performed by the refresh control logic 311, then undergo one or more power state transitions to a powered-off state (e.g., ACPI G2 or G3), a sleep state (e.g., ACPI G1), or back to a powered-on state prior to a subsequent second (i.e., (n+1)^{th}) refresh in the series of multiple refreshes.

At block 413, if a change in the memory refresh interval for one of the memory regions has been received, the process 400 continues at block 415. A change in the memory refresh interval may be initiated in response to, for example, a detected change in environmental conditions (such as a change in temperature detected by one or more temperature sensors), a change in operational mode of the memory region, or another event that affects the retention time of the memory region. At block 415, the refresh control logic 311 compares the new refresh interval with the old memory refresh interval. If the new refresh interval is not less than the old refresh interval, then the process 400 continues at block 417, where the refresh control logic 311 updates the refresh interval in the refresh table 325 in the memory 231, which serves as the backing store for cache 313, and updates or invalidates the corresponding value in the cache 313. The new refresh interval value can eventually be cached in the refresh table cache 313 through the course of normal operation.

If, at block 415, the new refresh interval is less than the old refresh interval, the process 400 continues at block 419, where the refresh control logic 311 updates the refresh interval by a write-through operation to update the refresh table cache 313 and the refresh table 325 in memory 231 at substantially the same time and with a single command. By performing a write-through update of the refresh interval when the new refresh interval is shorter than the old refresh interval, the refresh control logic 311 reduces the likelihood of performing the next refresh too late based on the old refresh interval, and risking data loss. From block 417 or 419, the process 400 continues back to block 401.

At block 401, the new memory refresh interval is stored in the refresh table 325, and the process repeats the operations of blocks 401-413 as previously described, using the new memory refresh interval. Thus, the refresh control logic 311, in response to changing of the memory refresh interval, performs the series of memory refreshes at a different frequency that is indicated by the new memory refresh interval.

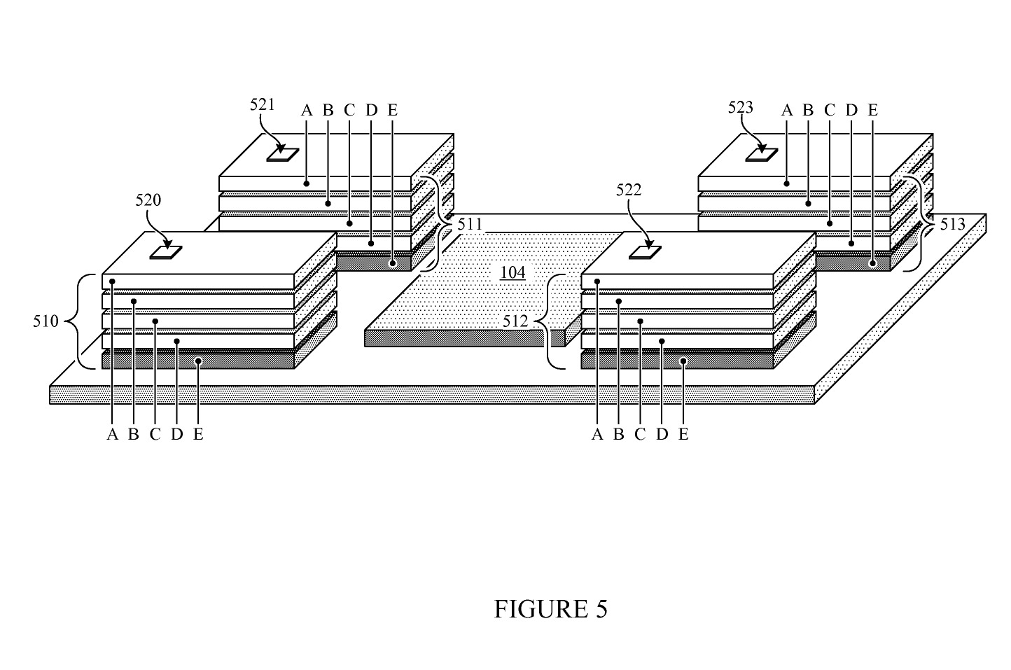

FIG. 5 illustrates an embodiment of a processing node of a processor-in-memory (PIM) system in which the memory retention controller 210 may be implemented. The processing node also includes the host processor 104, which is mounted on a substrate with a memory structure, including memory dies arranged in multiple memory stacks 510, 511, 512, and 513. Each of the memory stacks 510-513 comprises stacked dies A, B, C, D, and E. As referenced herein, individual dies are identified by the reference characters of their respective memory stacks, followed by the letter A, B, C, D, or E identifying the position of the die within the stack. For example, dies 210E, 211E, 212E, and 213E are logic dies located at the bottoms of the memory stacks 210, 211, 212, and 213, respectively. The A, B, C, and D dies in each of the stacks 210-213 are memory dies.

Each of the memory stacks 210-213 includes multiple memory regions for which memory refresh intervals are separately maintained, and also includes a memory retention controller and memory controllers implemented in a logic die of the memory stack. For example, the memory retention controller 210 and memory controllers 221 and 222 are located on logic die 510E, while the memory regions 231 and 232 are located on the memory dies 510A-510D. In some embodiments, one or more of the logic dies E can also include other components such as the master memory retention controller 209 and timer 245.

As illustrated in FIG. 5, temperature sensors 520-523 are attached to memory stacks 510-513, respectively. These temperature sensors 520-523 are used to detect changes in temperature that could affect retention times of the memory regions in the stacks 510-513. For example, temperature sensor 520 may detect an increase in temperature, resulting in a decreased retention time for the memory regions 231 and 232 residing in memory stack 510. In response, the memory retention controller 210 residing in the logic die 510E may shorten the memory refresh interval for the memory regions 231 and 232, thereby increasing the frequency of memory refreshes for the memory regions 231 and 232. In alternative embodiments, other types of environmental sensors may be used in addition to or instead of temperature sensors 520-523 to detect changes in environmental conditions and adjust memory refresh intervals accordingly.

In alternative embodiments, a memory retention controller can reside in various other places (e.g., on a host processor chip, on individual memory devices, on a dual in-line memory module (DIMM) buffer chip, a peripheral card, a disk drive, etc.) besides or in addition to a logic die of a memory stack. FIG. 5 illustrates a PIM node including four memory stacks and a host processor; however, alternative embodiments may have fewer or more memory stacks with fewer or more logic dies and memory dies that may be arranged in various orders within their respective stacks. Alternative embodiments may also have fewer or more processors. Memory retention controllers as described above may also be implemented in memory systems that are not PIM memory systems.

The embodiments described herein may include various operations. These operations may be performed by hardware components, software, firmware, or a combination thereof. As used herein, the term “coupled to” may mean coupled directly or indirectly through one or more intervening components. Any of the signals provided over various buses described herein may be time multiplexed with other signals and provided over one or more common buses. Additionally, the interconnection between circuit components or blocks may be shown as buses or as single signal lines. Each of the buses may alternatively be one or more single signal lines and each of the single signal lines may alternatively be buses.

Certain embodiments may be implemented as a computer program product that may include instructions stored on a non-transitory computer-readable medium. These instructions may be used to program a general-purpose or special-purpose processor to perform the described operations. A computer-readable medium includes any mechanism for storing or transmitting information in a form (e.g., software, processing application) readable by a machine (e.g., a computer). The non-transitory computer-readable storage medium may include, but is not limited to, magnetic storage medium (e.g., floppy diskette); optical storage medium (e.g., CD-ROM); magneto-optical storage medium; read-only memory (ROM); random-access memory (RAM); erasable programmable memory (e.g., EPROM and EEPROM); flash memory, or another type of medium suitable for storing electronic instructions.

Additionally, some embodiments may be practiced in distributed computing environments where the computer-readable medium is stored on and/or executed by more than one computer system. In addition, the information transferred between computer systems may either be pulled or pushed across the transmission medium connecting the computer systems.

Generally, a data structure representing the memory retention controller 210 and/or portions thereof carried on the computer-readable storage medium may be a database or other data structure which can be read by a program and used, directly or indirectly, to fabricate the hardware comprising the memory retention controller 210. For example, the data structure may be a behavioral-level description or register-transfer level (RTL) description of the hardware functionality in a high level design language (HDL) such as Verilog or VHDL. The description may be read by a synthesis tool which may synthesize the description to produce a netlist comprising a list of gates from a synthesis library. The netlist comprises a set of gates which also represent the functionality of the hardware comprising the memory retention controller 210. The netlist may then be placed and routed to produce a data set describing geometric shapes to be applied to masks. The masks may then be used in various semiconductor fabrication steps to produce a semiconductor circuit or circuits corresponding to the memory retention controller 210. Alternatively, the database on the computer-readable storage medium may be the netlist (with or without the synthesis library) or the data set, as desired, or Graphic Data System (GDS) II data.

Although the operations of the method(s) herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

In the foregoing specification, the embodiments have been described with reference to specific exemplary embodiments thereof. It will, however, be evident that various modifications and changes may be made thereto without departing from the broader spirit and scope of the embodiments as set forth in the appended claims. The specification and drawings are, accordingly, to be regarded in an illustrative sense rather than a restrictive sense.

What is claimed is:

1. A memory retention controller, comprising:
a data structure configured to store a memory refresh interval corresponding to a memory region in a memory subsystem; and
control logic coupled with the data structure and configured to
perform a first refresh of the memory region prior to a power off transition of a host processor coupled with the memory subsystem, and
perform a second refresh of the memory region after the power off transition of the host processor, based on the memory refresh interval corresponding to the memory region, and in response to an elapsed time since the first refresh of the memory region.

2. The memory retention controller of claim 1, wherein the data structure stores a next refresh time for the memory region, and wherein the control logic is configured to perform the second refresh at a time indicated by the next refresh time.

3. The memory retention controller of claim 1, wherein the control logic comprises refresh logic configured to perform the first refresh and the second refresh, wherein the first refresh and the second refresh are of a series of memory refreshes performed at a first frequency indicated by the memory refresh interval corresponding to the memory region.

4. The memory retention controller of claim 3, wherein the control logic is further configured to:
change the stored memory refresh interval in response to a detected environmental condition; and
in response to a change of the stored memory refresh interval to a new memory refresh interval, perform the series of memory refreshes at a second frequency indicated by the new memory refresh interval.

5. The memory retention controller of claim 4, further comprising a temperature sensor coupled with the control logic, wherein the detected environmental condition is an increase in temperature detected by the temperature sensor, and wherein the increase in the temperature corresponds to a new memory refresh interval that is shorter than the stored memory refresh interval.

6. The memory retention controller of claim 4, further comprising a cache memory coupled with the control logic and configured to store the data structure, wherein the control logic is further configured to, if the memory refresh interval is greater than the new memory refresh interval, store the new memory refresh interval by a write-through operation to the cache memory and a backing store of the cache memory.

7. The memory retention controller of claim 1, wherein a first clock signal coupled with the control logic has a lower frequency than a second clock signal coupled with the host processor, and wherein the control logic comprises near-threshold logic.

8. The memory retention controller of claim 1, wherein the control logic is further configured to initiate at least one of a plurality of memory maintenance operations on the memory region, wherein the plurality of memory maintenance operations comprises a memory scrubbing operation and a data migration operation.

9. The memory retention controller of claim 8, wherein control logic is configured to:
initiate a power on transition of the host processor; and
cause the host processor to perform the one or more memory maintenance operations on the memory region.

10. A method, comprising:
storing in a data structure a memory refresh interval corresponding to a memory region in a memory subsystem;
performing a first refresh of the memory region prior to a power off transition of a host processor coupled with the memory subsystem; and
performing a second refresh of the memory region after the power off transition of the host processor, based on the memory refresh interval corresponding to the memory region, and in response to an elapsed time since the first refresh of the memory region.

11. The method of claim 10, further comprising performing a series of memory refreshes at a first frequency indicated by the memory refresh interval corresponding to the memory region, wherein the series of memory refreshes includes the first refresh and the second refresh.

12. The method of claim 11, further comprising, in response to a change of the stored memory refresh interval to a new memory refresh interval, performing the series of memory refreshes at a second frequency indicated by the new memory refresh interval.

13. The method of claim 12, further comprising:
storing the data structure in a cache memory; and
if the memory refresh interval is greater than the new memory refresh interval, storing the new memory refresh interval by a write-through operation to the cache memory and a backing store of the cache memory.

14. The method of claim 10, further comprising:
initiating a power on transition of the host processor; and
causing the host processor to perform the one or more memory maintenance operations on the memory region.

15. A computing system, comprising:
a host processor;
a memory subsystem coupled with the host processor; and
a memory retention controller coupled with the memory subsystem, the memory retention controller comprising:
a data structure configured to store a memory refresh interval corresponding to a memory region in the memory subsystem, and
control logic coupled with the data structure and configured to
perform a first refresh of the memory region prior to a power off transition of the host processor, and
perform a second refresh of the memory region after the power off transition of the host processor, based on the memory refresh interval corresponding to the memory region, and in response to an elapsed time since the first refresh of the memory region.

16. The computing system of claim 15, further comprising an auxiliary power supply coupled with the memory retention controller and configured to supply power to the memory retention controller when the host processor is in a powered off state.

17. The computing system of claim 16, wherein control logic is further configured to:
initiate a power on transition of the host processor; and
cause the host processor to perform the one or more memory maintenance operations on the memory region.

18. The computing system of claim 15, further comprising a plurality of slave retention controllers including the memory retention controller, wherein each of the plurality of slave retention controllers is coupled with a master retention controller and stores one or more memory refresh intervals corresponding respectively to one or more memory regions of the memory subsystem.

19. The computing system of claim 18, wherein each slave retention controller of the plurality of slave retention controllers is configured to:
cause the master retention controller to transition from a lower power consumption state to a higher power consumption state; and
cause the master retention controller to initiate one or more memory maintenance operations on the memory region corresponding to the slave retention controller.

20. The computing system of claim 15, wherein the memory retention controller is located on a logic die in a memory stack, and wherein the memory region is located on one or more memory dies in the memory stack.
